(19) United States
(12) Patent Application Publication
(10) Pub. No.: US 2026/0282382 A1
(43) Pub. Date: Sep. 17, 2026

(54) SEMICONDUCTOR DEVICE INCLUDING VERTICAL CHANNEL

(71) Applicant: Samsung Electronics Co., Ltd., Suwon-si (KR)

(72) Inventors: Kang Lib Kim, Suwon-si (KR); Hongrae Jin, Suwon-si (KR)

(21) Appl. No.: 19/337,367

(22) Filed: Sep. 23, 2025

(30) Foreign Application Priority Data
Mar. 11, 2025 (KR) 10-2025-0031658

(51) Int. Cl. H10B 51/40; G11C 5/06; G11C 16/04; H10B 51/10; H10B 51/20; H10D 80/30; H10W 90/00

(52) U.S. Cl. CPC H10B 51/40; G11C 5/063; G11C 16/0483; H10B 51/10; H10B 51/20; H10D 80/30; H10W 90/00; H10W 90/792

(57) ABSTRACT

The concepts discussed herein provide a device including a cell structure on top of a periphery circuit structure. The cell structure includes an alternating stack of gate electrodes and mold insulating layers. A contact plug connects to a specific gate electrode and extends downward into others below it. The contact plug is surrounded by insulating spacers with both vertical and horizontal extension units. The vertical extension units are in contact with the contact plug. The insulating spacers are also coupled with a dummy structure, which has a main body and multiple protrusions.

### CROSS-REFERENCE TO RELATED APPLICATION

This application is based on and claims ranking under 35 U.S.C. §119 to Korean Patent Application No. 10-2025-0031658, filed on Mar. 11, 2025, in the Korean Intellectual Property office, the disclosure of which is incorporated by reference herein in its entirety.

### BACKGROUND

The concepts discussed herein relate to a semiconductor device. More particularly, the concepts relate to semiconductor devices including vertical channels.

### SUMMARY

In an electronic system requiring a data storage, semiconductor devices capable of storing a large amount of data are required. Accordingly, methods have been studied to increase data storage capacity of semiconductor devices. For example, as one of the methods to increase data storage capacity of the semiconductor devices, a semiconductor device including three-dimensionally arranged memory cells instead of two-dimensionally arranged memory cells arranged in a two-dimension has been proposed.

The concepts discussed herein provides a semiconductor device having a simplified process flow and improved alignment precision, and a method of manufacturing the semiconductor device.

In addition, the issues to be solved by the concepts discussed herein are not limited to those mentioned above, and other issues may be clearly understood by those of ordinary skill in the art from the following descriptions.

The concept discussed herein provide semiconductor devices as described below.

According to an aspect of the concepts discussed herein, there is provided a semiconductor device including a periphery circuit structure, and a cell structure arranged on the periphery circuit structure and including a cell region and a connection region, wherein the cell structure includes gate electrodes and mold insulating layers alternately arranged in the cell region and the connection region in a first direction perpendicular to an upper surface of the periphery circuit structure, a channel structure configured to penetrate the gate electrodes and extend in the first direction, a contact plug in contact with a first gate electrode among the gate electrodes in the connection region, and configured to penetrate second gate electrodes arranged under the first gate electrode among the gate electrodes, a dummy structure arranged adjacent to the contact plug, and including a body configured to extend in the first direction and a plurality of protrusion units extending from the body in a second direction crossing the first direction, and insulating spacers surrounding the contact plugs and connected to at least one protrusion unit in one body, each of which includes vertical extension units arranged on sidewalls of the contact plugs and apart from each other in the first direction, and horizontal extension units each extending from the vertical extension unit in the second direction.

According to another aspect of the concepts discussed herein, there is provided a semiconductor device including a periphery circuit structure, and a cell structure arranged on the periphery circuit structure and including a cell region and a connection region, wherein the cell structure includes gate electrodes and mold insulating layers alternately arranged in the cell region and the connection region in a first direction perpendicular to an upper surface of the periphery circuit structure, a channel structure configured to penetrate the gate electrodes and extend in the first direction, a contact plug in contact with a first gate electrode among the gate electrodes in the connection region, and configured to penetrate second gate electrodes arranged under the first gate electrode among the gate electrodes, a first dummy structure including a body arranged adjacent to the contact plug and including one side surface extending in the first direction and facing the contact plug and another side surface opposite to the one side surface, a plurality of first protrusion units extending from the one side surface of the body in a second direction crossing the first direction, and a plurality of second protrusion units extending from the other side surface in the second direction, and an insulating spacer including vertical extension units surrounding the contact plugs, arranged on both sidewalls of the contact plugs, and being apart from each other in the first direction, a plurality of first horizontal extension units extending from the vertical extension units in a direction toward the first dummy structure, and a plurality of second horizontal extension units extending in a direction opposite to the first dummy structure, wherein the plurality of first horizontal extension units of the insulating spacer are included in the plurality of first protrusion units of the first dummy structure, and wherein there is no interface between the first dummy structure and the insulating spacer.

The concepts discussed herein provide at least one method of manufacturing semiconductor devices.

According to another aspect of the concepts discussed herein, there is provided at least one method of manufacturing semiconductor devices including forming a mold stack by alternately stacking sacrificial layers and mold insulating layers on a substrate having a cell region and a connection region, in the connection region, forming a plurality of dummy holes configured to penetrate the mold stack, in the connection region, forming a contact plug hole adjacent to each of the plurality of dummy holes, forming a plurality of recesses by removing portions of the sacrificial layers exposed by the plurality of dummy holes and the contact plug holes at a certain thickness, forming a preliminary spacer by forming the plurality of dummy structures by filling spaces of the plurality of dummy holes and the plurality of recesses with a first filling material and simultaneously covering inside walls and bottoms of the plurality of contact plug holes at a conformal thickness, filling remaining spaces of the plurality of contact plug holes with a second insulating material, after removing all of the sacrificial layers, forming gate electrodes in spaces from which the sacrificial layers have been removed, leaving spacers arranged on the inside walls of the plurality of contact plug holes by removing the second insulating material and removing the first insulating material surrounding the plurality of contact plug holes of the preliminary spaces, and forming a contact plug by filling a conductive material in the left spaces of the plurality of contact plug holes.

### BRIEF DESCRIPTION OF THE DRAWINGS

Implementations of the concepts discussed herein will be more clearly understood from the following detailed description taken in conjunction with the accompanying drawings in which:

FIG. 1 is a block diagram of a semiconductor device according to at least one implementation;

FIG. 2 is an equivalent circuit diagram of a memory cell array of a semiconductor device, according to at least one implementation;

FIG. 3 is a perspective view of a representative configuration of a semiconductor device, according to at least one implementation;

FIG. 4 is a plan view of the semiconductor device of FIG. 3;

FIG. 5 is a cross-sectional view of the semiconductor device of FIG. 3 taken along line A - A' in FIG. 4;

FIG. 6 is an enlarged view of region EX1 in FIG. 5;

FIG. 7 is a partial enlarged cross-sectional view of the semiconductor device of FIG. 3 taken along line B - B' in FIG. 4;

FIG. 8 is another enlarged view of region EX1 in FIG. 5; and

FIGS. 9-20, and 21 are cross-sectional views of portions of a method of manufacturing a semiconductor device, according to implementations.

### DETAILED DESCRIPTION

Hereinafter, implementations of the concepts discussed herein are described in detail with reference to accompanying diagrams. Identical reference numerals are used for the same constituent devices in the drawings, and duplicate descriptions thereof are omitted.

Because various changes may be applied to the implementations and the concepts discussed herein may have various implementations, particular implementations are illustrated in the diagrams and described in detail. However, this is not intended to limit the inventive concept to particular modes of practice, and it is to be appreciated that all changes, equivalents, and substitutes, which do not depart from the spirit and technical scope of the inventive concept, are encompassed in the inventive concept. In the description of the implementations, certain detailed explanations of the related art are omitted when it is deemed that they may unnecessarily obscure the essence of the implementations.

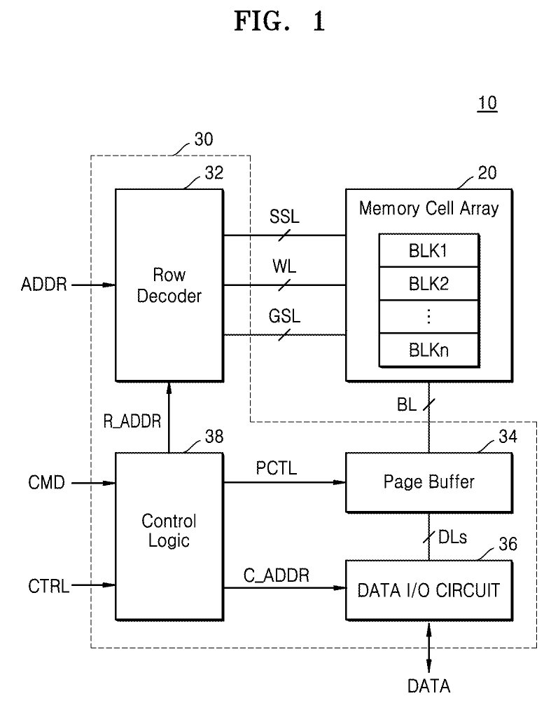

FIG. 1 is a block diagram of a semiconductor device 10 according to at least one implementation.

Referring to FIG. 1, the semiconductor device 10 may include a memory cell array 20 and a periphery circuit 30. The memory cell array 20 may include a plurality of memory cell blocks BLK1, BLK2, ..., BLKn. Each of the plurality of memory cell blocks BLK1, BLK2, ..., BLKn may include a plurality of memory cells. The plurality of memory cell blocks BLK1, BLK2, ..., BLKn may be connected to the periphery circuit 30 via a bit line BL, a word line WL, a string selection line SSL, and a ground selection line GSL.

The periphery circuit 30 may include a row decoder 32, a page buffer 34, a data input/output (I/O) circuit 36, and a control logic 38. Although not illustrated in FIG. 1, the periphery circuit 30 may further include an I/O interface, a column logic, a voltage generator, a pre-decoder, a temperature sensor, a command decoder, an address decoder, an amplification circuit, etc.

The memory cell array 20 may be connected to the page buffer 34 via the bit line BL, and may be connected to the row decoder 32 via the word line WL, the string selection line SSL, and the ground selection line GSL. In the memory cell array 20, each of the plurality of memory cells included in the plurality of memory cell blocks BLK1, BLK2, ..., BLKn may include a flash memory cell. The memory cell array 20 may include a three-dimensional memory cell array. The three-dimensional memory cell array may include a plurality of NAND strings, and each NAND string may include a plurality of memory cells connected to a plurality of word lines WL, which are vertically stacked on a substrate.

The periphery circuit 30 may receive an address ADDR, a command CMD, and a control signal CTRL from the outside of the semiconductor device 10, and may transceive data DATA to/from a device outside the semiconductor device 10.

The row decoder 32 may select at least one of the plurality of memory cell blocks BLK1, BLK2, ..., BLKn in response to the address ADDR provided from the outside of the semiconductor device 10, and may select the word line WL, the string selection line SSL, and the ground selection line GSL of a selected memory cell block. The row decoder 32 may transmit a voltage for performing a memory operation to the word line WL of the selected memory cell block.

The page buffer 34 may be connected to the memory cell array 20 via the bit line BL. The page buffer 34 may act as a write driver during a program operation to apply, to the bit line BL, a voltage according to the data DATA to be stored in the memory cell array 20, and operate as a sensing amplifier during a read operation to detect the data DATA stored in the memory cell array 20. The page buffer 34 may operate according to a control signal CTRL provided by the control logic 38.

The data I/O circuit 36 may be connected to the page buffer 34 via data lines DL. The data I/O circuit 36 may receive the data DATA from a memory controller (not illustrated) during the program operation, and provide the data DATA for a program operation to the page buffer 34 based on a column address C_ADDR provided by the control logic 38. The data I/O circuit 36 may provide, to the memory controller (not illustrated), the data DATA for a read operation stored in the page buffer 34 based on the column address C_ADDR provided by the control logic 38 during the read operation.

The data I/O circuit 36 may transmit an address or a command to be input, to the control logic 38 or the row decoder 32. The periphery circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32, and provide a column address C_ADDR to the data I/O circuit 36. The control logic 38 may generate various internal control signals to be used by the semiconductor device 10 in response to the control signal CTRL. For example, the control logic 38 may control voltage levels to be provided to the word line WL and the bit line BL, when memory operations, such as a program operation and an erase operation, are performed.

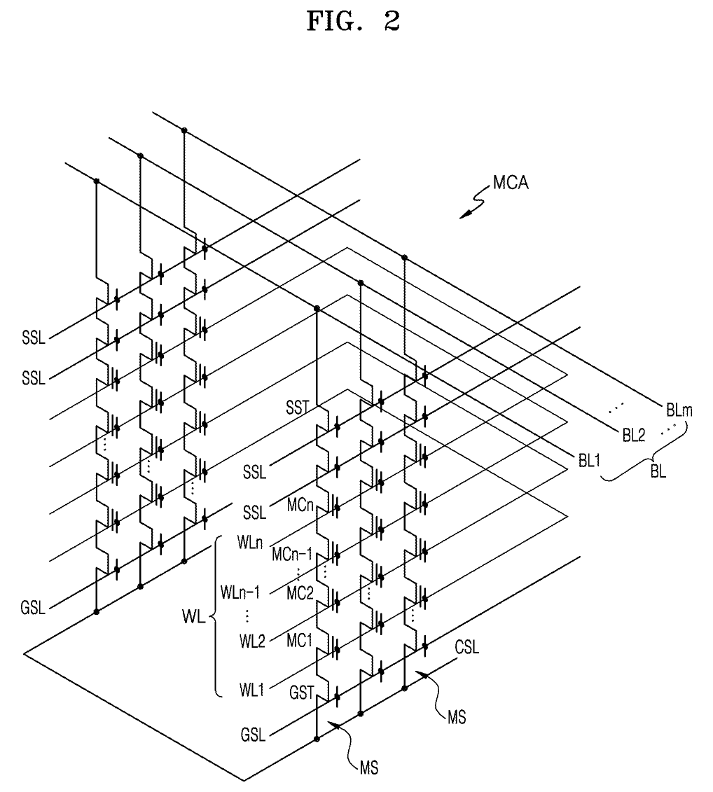

FIG. 2 is an equivalent circuit diagram of a memory cell array MCA of the semiconductor device 10, according to at least one implementation.

Referring to FIG. 2, the memory cell array MCA may include a plurality of memory cell strings MS. The memory cell array MCA may include a plurality of bit lines BL (including BL1, BL2, …, BLm), a plurality of word lines WL (including WL1, WL2, …, WLn-1, WLn), at least one string selection line SSL, at least one ground selection line GSL, and a common source line CSL. The plurality of memory cell strings MS may be formed between the plurality of bit lines BL (including BL1, BL2, …, BLm) and the common source line CSL. In FIG. 2, the case in which each of the plurality of memory cell strings MS includes two string selection lines SSL is illustrated, but the implementation is not limited thereto. For example, each of the plurality of memory cell strings MS may also include one string selection line SSL.

Each of the plurality of memory cell strings MS may include a string selection transistor SST, a ground selection transistor GST, and a plurality of memory cell transistors MC1, MC2, …, MCn-1, MCn. A drain region of the string selection transistor SST may be connected to the plurality of bit lines BL (including BL1, BL2, …, BLm), and a source region of the ground selection transistor GST may be connected to the common source line CSL. The common source line CSL may include a region, to which the source regions of a plurality of ground selection transistors GST are connected in common.

The string selection transistor SST may be connected to the string selection line SSL, and the ground selection transistor GST may be connected to the ground selection line GSL. The plurality of memory cell transistors MC1, MC2, …, MCn-1, MCn may be connected to the plurality of word lines WL (including WL1, WL2, …, WLn-1, and WLn), respectively.

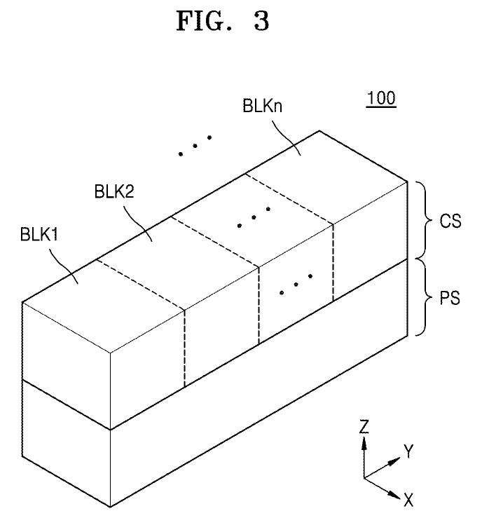

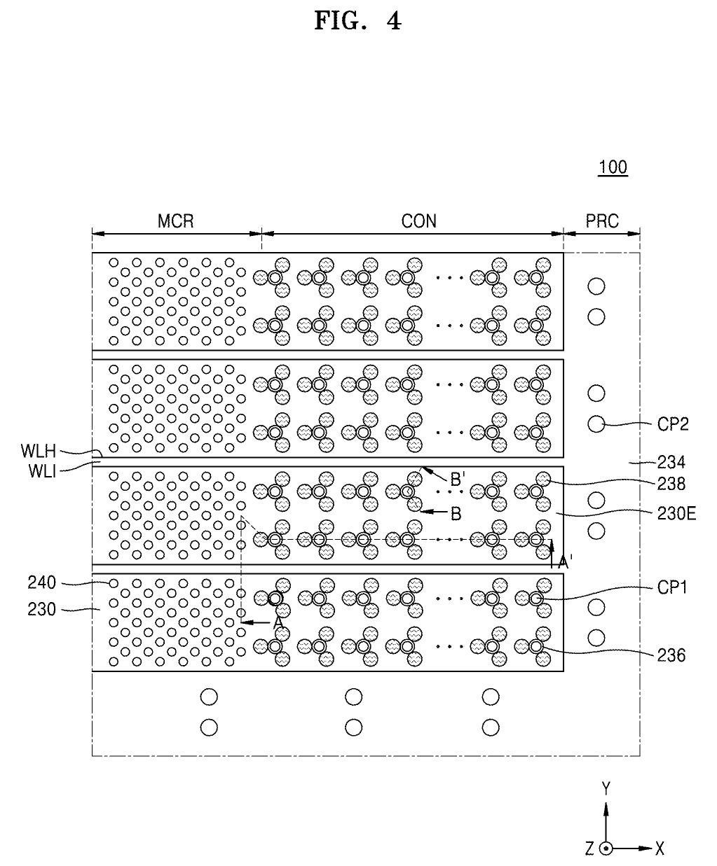

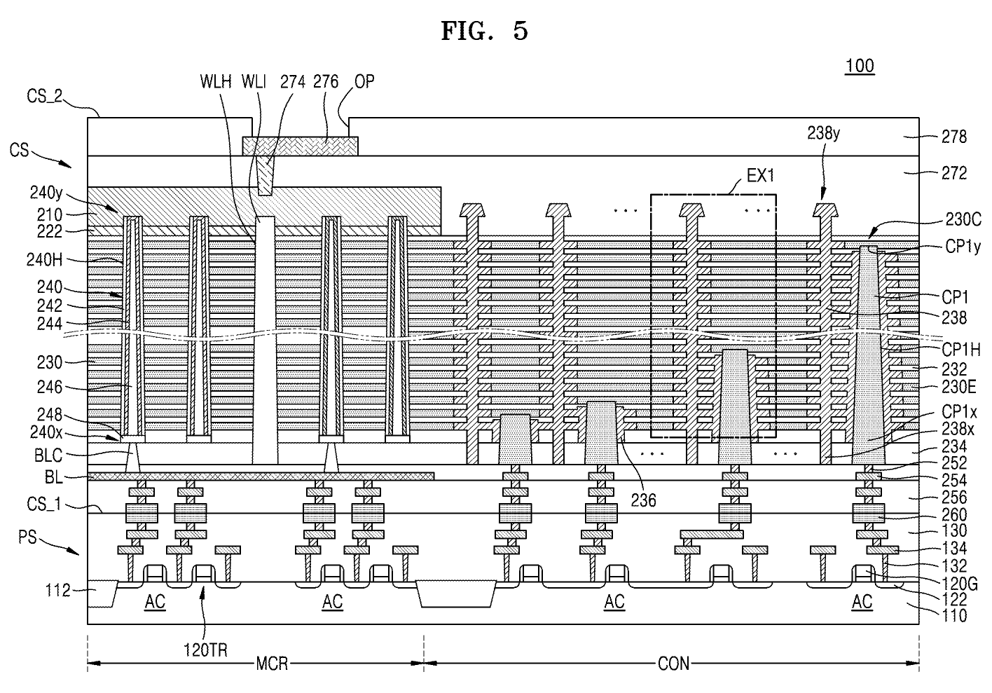

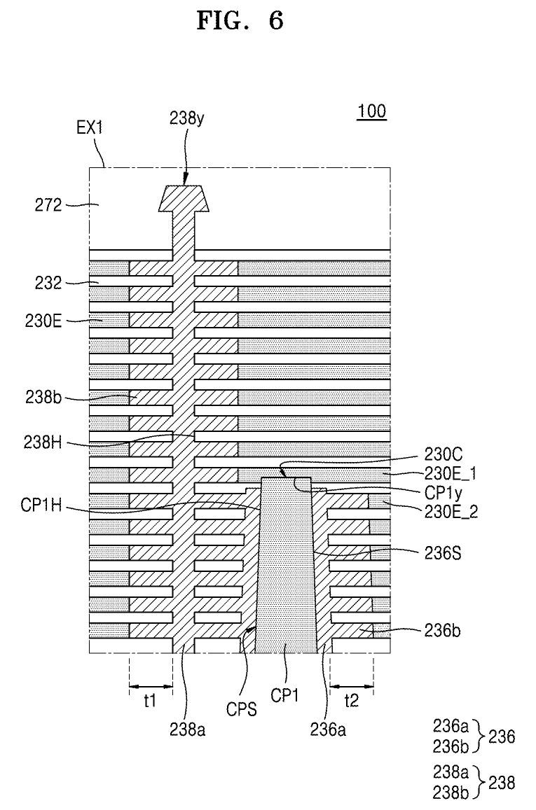

FIG. 3 is a perspective view of a representative configuration of a semiconductor device 100, according to at least one implementation. FIG. 4 is a plan view of the semiconductor device 100 of FIG. 3. FIG. 5 is a cross-sectional view of the semiconductor device of FIG. 3 taken along line A - A' in FIG. 4. FIG. 6 is an enlarged view of region EX1 in FIG. 5.

Referring to FIGS. 3-6, the semiconductor device 100 may include a cell structure CS and a periphery circuit structure PS, which overlap each other in a vertical direction (Z direction). The cell structure CS may include the memory cell array 20 described with reference to FIG. 1, and the periphery circuit structure PS may include the periphery circuit 30 described with reference to FIG. 1.

The cell structure CS may include the plurality of memory cell blocks BLK1, BLK2, ..., BLKn. Each of the plurality of memory cell blocks BLK1, BLK2, ..., BLKn may include memory cells, which are three-dimensionally arranged.

The periphery circuit structure PS may include a periphery circuit transistor 120TR arranged on a substrate 110. On the substrate 110, an active region AC may be defined by a device separation layer 112, and a plurality of periphery circuit transistors 120TR may be formed on the active region AC. The plurality of periphery circuit transistors 120TR may include a periphery circuit gate 120G, and a source/drain region 122 arranged in portions of the substrate 110 on both sides of the periphery circuit gate 120G.

The substrate 110 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium (SiGe). The substrate 110 may also be provided as a bulk wafer or an epitaxial layer. In another implementation, the substrate 110 may include a silicon-on-insulator (SOI) substrate or a germanium-on-insulator (GeOI) substrate.

A plurality of periphery circuit contacts 132 and a plurality of periphery circuit wiring layers 134 may be arranged on an upper surface of the substrate 110. An interlayer insulating layer 130 covering the periphery circuit transistor 120TR, the plurality of periphery circuit contacts 132, and the plurality of periphery circuit wiring layers 134 may be arranged on the substrate 110. The plurality of periphery circuit wiring layers 134 may have a multilayer structure including a plurality of metal layers arranged at different vertical levels. A connection pad 260 may be arranged on the interlayer insulating layer 130, and the periphery circuit structure PS and the cell structure CS may be electrically connected and bonded to each other via the connection pad 260.

The cell structure CS may include a cell region MCR, a connection region CON, and a periphery circuit connection region PRC. The cell region MCR may be a region in which a memory cell block BLK including the plurality of memory cell strings MS extending in the vertical direction (Z direction) is arranged. In the cell region MCR, a common source layer 210, a plurality of gate electrodes 230, and a channel structure 240, which penetrates the plurality of gate electrodes 230, extends in the vertical direction (Z direction), and is connected to the common source layer 210, may be arranged. In the connection region CON, a plurality of gate extension units 230E respectively connected to the plurality of gate electrodes 230, and a plurality of first plugs CP1 electrically and respectively connected to the plurality of gate extension units 230E may be arranged. In the periphery circuit connection region PRC, a second plug CP2, which extends in the vertical direction (Z direction) and is electrically connected to the periphery circuit wiring layer 134, may be arranged.

The cell structure CS may include a first surface CS_1 connected to the periphery circuit structure PS, and a second surface CS_2 opposite to the first surface CS_1. FIG. 5 illustrates that the first surface CS_1 of the cell structure CS is arranged on a lower side of the cell structure CS, and the second surface CS_2 of the cell structure CS is arranged on an upper side of the cell structure CS. In this case, for convenience, as illustrated in FIG. 5, an arrangement close to the first surface CS_1 of the cell structure CS may be referred to as an arrangement at a lower vertical level, and an arrangement close to the second surface CS_2 of the cell structure CS may be referred to as an arrangement at a higher vertical level.

The gate electrodes 230 may be arranged apart from each other in the cell region MCR in the vertical direction (Z direction), and may be alternately arranged with mold insulating layers 232. The gate electrodes 230 may extend to the connection region CON, and portions of the gate electrodes 230 arranged in the connection region CON may be referred to as the gate extension units 230E. The gate extension units 230E arranged apart from each other in the vertical direction (Z direction) may have the same width in a first horizontal direction (X direction).

In some implementations, the gate electrodes 230 may include a metal, such as tungsten, nickel, cobalt, and tantalum, a metal silicide, such as tungsten silicide, nickel silicide, cobalt silicide, and tantalum silicide, and polysilicon doped with impurities, or a combination thereof.

According to some implementations, the gate electrodes 230 may correspond to ground selection lines GSL constituting memory cell strings MS, word lines WL, and at least one of string selection lines SSL. For example, the gate electrodes 230 at the uppermost portion may function as the ground selection lines GSL, two of gate electrodes 230 at the lowermost portion may function as the string selection lines SSL, and the remaining gate electrodes 230 may function as the word lines WL. Accordingly, the ground selection transistor GST, the string selection transistor SST, and memory cell strings MS, to which the memory cell transistors MC between the ground selection transistor GST and the string selection transistor SST are directly connected, may be provided. In at least one implementation, at least one of the gate electrodes 230 may also function as a dummy word line, but the implementation is not limited thereto.

A stack separation insulating layer WLI may be arranged in a stack separation opening unit WLH, which penetrates the gate electrodes 230 and the mold insulating layers 232 and extends in the vertical direction (Z direction). The stack separation insulating layer WLI may have an upper surface thereof at a higher vertical level than the gate electrode 230 at the uppermost portion, and may protrude upward with reference to the gate electrode 230. In some implementations, the gate electrodes 230 arranged between a pair of stack separation opening units WLH may constitute one block.

The channel structure 240 may be arranged in a channel hole 240H penetrating the gate electrodes 230 and the mold insulating layers 232 and extending in the vertical direction (Z direction). The channel structure 240 may include a gate insulating layer 242, a channel layer 244, a buried insulating layer 246, and a drain region 248. The gate insulating layer 242, the channel layer 244, and the buried insulating layer 246 may be sequentially arranged on internal walls of the channel hole 240H.

The channel structure 240 may include a first end unit 240x arranged close to the periphery circuit structure PS, and a second end unit 240y opposite to the first end unit 240x. In some implementations, the channel structure 240 may have a sidewall inclined so that a width of the first end unit 240x is greater than a width of the second end unit 240y.

The drain region 248 electrically connected to the channel layer 244 may be arranged at the first end unit 240x of the channel structure 240. The drain region 248 may be connected to a bit line contact BLC, and the channel layer 244 may be electrically connected to the bit line BL via the drain region 248 and the bit line contact BLC. An upper surface of the channel layer 244 at the second end unit 240y of the channel structure 240 may not be covered by the gate insulating layer 242, and the common source layer 210 may be connected to the upper surface of the channel layer 244.

In some implementations, the gate insulating layer 242 may have a structure including a tunneling dielectric layer, a charge storage layer, and a blocking dielectric layer sequentially arranged on an outside wall of the channel layer 244. The charge storage layer may include a region in which electrons having penetrated the tunneling dielectric layer from the channel layer 244 are stored, and may include silicon nitride, boron nitride, silicon boron nitride, or impurities-doped polysilicon.

In some implementations, the charge storage layer may include a ferroelectric dielectric material. In this case, the charge storage layer may include a metal oxide having ferroelectric material properties. For example, the charge storage layer may contain ferroelectric materials that can store data by using hysteresis behavior due to a voltage applied to the charge storage layer. In some implementations, the charge storage layer may include at least one of hafnium oxide, zirconium oxide, and hafnium zirconium oxide.

An etching stop layer 222 may be arranged on the gate electrode 230 that is uppermost, and may include polysilicon. In some implementations, the etching stop layer 222 may be omitted.

The common source layer 210 may be conformally formed on the etching stop layer 222 to be connected to the second end unit 240y of the channel structure 240 and to cover an upper surface of the stack separation insulating layer WLI. In a plan view, the common source layer 210 may be arranged in the entirety of the cell region MCR.

In some implementations, the common source layer 210 may include at least one of Si, Ge, silicon germanium (SiGe), gallium arsenide (GaAs), indium gallium arsenide (InGaAs), aluminum gallium arsenide (AlGaAs), or a combination thereof. In addition, the common source layer 210 may include a semiconductor doped with n-type impurities. In addition, the common source layer 210 may have a crystal structure including at least one of a single crystal structure, an amorphous structure, and a polycrystalline structure. In some implementations, the common source layer 210 may include polysilicon doped with n-type impurities.

Between a stack cover insulating layer 234 and the periphery circuit structure PS, a connection via 252, a connection wiring layer 254, and an interlayer insulating layer 256 surrounding the connection via 252 and the connection wiring layer 254 may be arranged. The connection via 252 and the connection wiring layer 254 may be configured to include multiple layers to be arranged at a plurality of vertical levels, and the bit line BL, the first plug CP1, and the second plug CP2 may be electrically connected to the periphery circuit structure PS via the connection pad 260.

A plurality of gate electrodes 230 may extend in the cell region MCR and the connection region CON in a horizontal direction. The gate electrodes 230 arranged in the connection region CON may be referred to as a gate extension unit 230E. A plurality of gate extension units 230E may overlap each other in the connection region CON in the vertical direction (Z direction). For example, a plurality of gate extension units 230E arranged at different vertical levels in the connection region CON may have the same width in the horizontal direction.

The plurality of first plugs CP1 may penetrate the stack cover insulating layer 234, the mold insulating layer 232, and the plurality of gate extension units 230E in the connection region CON, and extend in the vertical direction (Z direction). The plurality of first plugs CP1 may have widths changing in the vertical direction (Z direction). In some implementations, each of the plurality of first plugs CP1 may include a first end unit CP1x and a second end unit CP1y, and the first end units CP1x of the plurality of first plugs CP1 may all be arranged at the same vertical level, and in addition, may be arranged at the same vertical level as an upper surface of the stack cover insulating layer 234. The second end units CP1y of the plurality of first plugs CP1 may be arranged at different vertical levels, and for example, each of the second end units CP1y of the plurality of first plugs CP1 may be arranged on a gate contact surface 230C corresponding to each second end unit CP1y.

In some implementations, a bottom surface of each of the plurality of first plugs CP1 may be in contact with the gate contact surface 230C, and accordingly, one of the first plug CP1 may be electrically connected to the gate extension unit 230E corresponding to the one of the first plug CP1 via the gate contact surface 230C (for example, a first gate electrode extension unit 230E_1 illustrated in FIG. 6). In some implementations, a sidewall of each of the plurality of first plugs CP1 may be surrounded by an insulating spacer 236. For example, between one of the plurality of first plugs CP1 and each of the plurality of gate extension units 230E, the insulating spacer 236 corresponding thereto may be arranged. A detailed description of the insulating spacer 236 is given below.

In some implementations, a bottom surface of one of the first plug CP1 may be electrically connected to the gate extension unit 230E corresponding thereto (for example, a first gate electrode extension unit 230E_2 illustrated in FIG. 6), while the sidewall of one of the first plug CP1 may not be electrically connected to the gate extension unit 230E arranged at a lower vertical level than the gate extension unit 230E corresponding to the sidewall (for example, a second gate electrode extension unit 230E_2 illustrated in FIG. 6). The insulating spacer 236 may be arranged between the gate extension unit 230E corresponding thereto (for example, the second gate electrode extension unit 230E_2 arranged at a lower vertical level than the first gate electrode extension unit 230E_1) (for example, the second gate electrode extension unit 230E_2) and the sidewall of one of the first plug CP1, and accordingly, the gate extension unit 230E arranged at a lower vertical level than the gate extension unit 230E corresponding to the insulating spacer 236 (for example, the second gate electrode extension unit 230E_2) may be insulated from the sidewall of the one of the first plug CP1. In this case, the gate extension unit 230E arranged at a lower vertical level than the gate extension unit 230E corresponding thereto (for example, the second gate electrode extension unit 230E_2) may be referred to as the gate extension unit 230E arranged closer to the periphery circuit structure PS than the gate extension unit 230E corresponding thereto.

In some implementations, the first plug CP1 may include a metal, such as tungsten, nickel, cobalt, and tantalum, a metal silicide, such as tungsten silicide, nickel silicide, cobalt silicide, and tantalum silicide, polysilicon doped with impurities, or a combination thereof. In some implementations, the insulating spacer 236 may include silicon oxide. In some implementations, the insulating spacer 236 may include a silicon oxide containing a small amount of any one element of chlorine, fluorine, or bromine (for example, 5 atomic percent (at%) or less).

In some implementations, the insulating spacer 236 may include a vertical extension unit 236a and a horizontal extension unit 236b. The vertical extension unit 236a of the insulating spacer 236 may be formed to have a constant thickness along the sidewall of each of the plurality of first plugs CP1, may extend in a direction crossing the direction in which the plurality of gate electrodes 230 extend, and the horizontal extension unit 236b of the insulating spacer 236 may extend in the same horizontal direction as the direction in which the plurality of gate electrodes 230 extend from the vertical extension unit 236a. As to be described below, the vertical extension unit 236a and the horizontal extension unit 236b of the insulating spacer 236 may be integrally formed, and may include substantially the same material. The vertical extension unit 236a of the insulating spacer 236 may extend substantially perpendicular to the direction in which the plurality of gate electrodes 230 extend, but because the plurality of first plugs CP1 have, as a whole, a tapered shape in which a horizontal width of the plurality of first plugs CP1 is reduced in a direction away from the upper surface of the substrate 110, the vertical extension unit 236a may also be formed with an inclination with respect to the upper surface of the substrate 110. Here substantially perpendicular refers to an angle that is within +/- 5 degrees from 90 degrees.

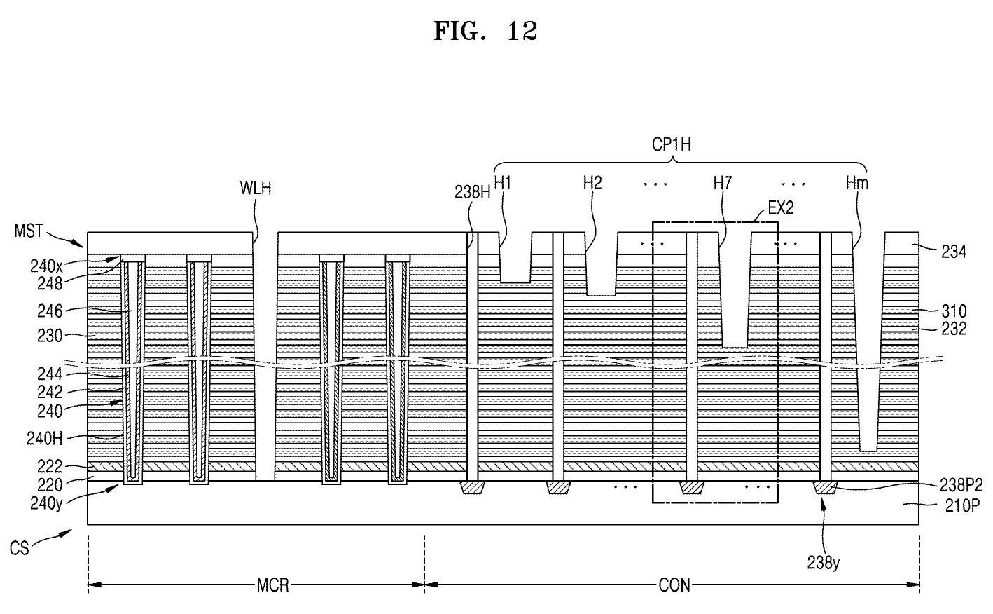

However, in some other implementations, unlike as illustrated in FIGS. 5 and 6, the sidewalls of the plurality of first plugs CP1 may not have a tapered shape with a constant slope in all regions, but may include at least one jawed shape on the sidewalls. This may be a result of a process operation for forming the first plug CP1, and the reason may be because an etching process operation for forming a first plug hole CP1H (refer to FIG. 12) may be performed multiple times instead of one time. Accordingly, in some implementations, the jawed shape may be observed on the sidewalls of the first plug CP1. As illustrated in FIG. 6, a side surface CPS of each of the plurality of first plugs CP1 may be in contact with the sidewalls 236S of a plurality of insulating spacers 236. Thus, the side surface CPS of the plurality of first plugs CP1 may have the same inclined profile as the sidewall 236S of the insulating spacer 236.

In some implementations, the insulating spacer 236 may have a ring-shaped horizontal cross-section. As illustrated in FIG. 6, each horizontal extension unit 236b of the insulating spacer 236 may be arranged at the same vertical level as the gate extension unit 230E facing the insulating spacer 236 (for example, the second gate electrode extension unit 230E_2). In addition, the height in the vertical direction (Z direction) of each horizontal extension unit 236b of the insulating spacer 236 may be the same as the height in the vertical direction of the gate extension unit 230E (for example, the second gate electrode extension unit 230E_2).

In some implementations, a dummy structure 238 may be formed adjacent to each of the plurality of first plugs CP1. The dummy structure 238 may, in the connection region CON, penetrate the gate electrodes 230 and the mold insulating layers 232 and extend in the vertical direction (Z direction). The dummy structure 238 may be formed to prevent leaning, bending, or the like of the gate electrode 230 in the manufacturing process operation of the semiconductor device 100, and secure structural stability of the semiconductor device 100. Although the concepts discussed herein illustrate that a total of three of the dummy structures 238 adjacent to one of the first plug CP1 are formed (see FIG. 4), this is only an example illustration, and the number of dummy structures 238 may not limit the technical idea of the concepts discussed herein. In some implementations, the dummy structure 238 may include an insulating material.

In some implementations, the dummy structure 238 may include a first end unit 238x arranged close to the periphery circuit structure PS and a second end unit 238y opposite the first end unit 238x. Referring to FIGS. 5 and 6, the second end unit 238y, unlike the first end unit 238x, is illustrated to further include a protrusion unit of a trapezoidal shape, but the concepts discussed herein is not limited thereto. In addition, the sidewall of the dummy structure 238 is illustrated to extend in the vertical direction (Z direction) perpendicular to the upper surface of the substrate 110, but due to a difference in etching selectivity in some other implementations, the dummy structure 238 may also have an inclined sidewall with a width reducing away from the upper surface of the substrate 110.

In some implementations, the dummy structure 238 may include a vertical extension unit 238a and a horizontal extension unit 238b. The vertical extension unit 238a of the dummy structure 238 may extend in the vertical direction (Z direction) in a region adjacent to the plurality of first plugs CP1, and the horizontal extension unit 238b of the dummy structure 238 may extend from the vertical extension unit 238a in a horizontal direction identical to a direction in which the plurality of gate electrodes 230 extend. As to be described below, the vertical extension unit 238a and the horizontal extension unit 238b of the dummy structure 238 may be integrally formed, and may include substantially the same material.

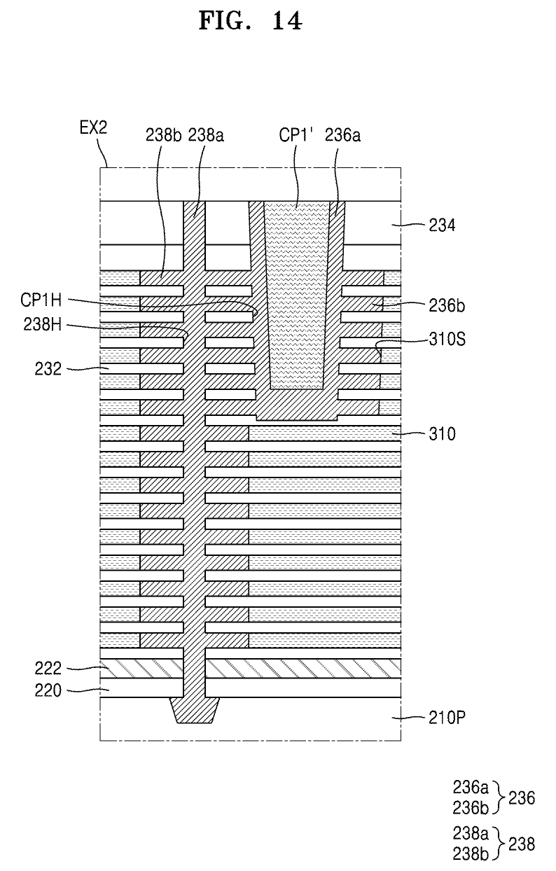

Furthermore, the dummy structure 238 and the insulating spacer 236 may be formed in one body (also referred to as integrally formed or integrally connected), and may include substantially the same material. In other words, because the dummy structure 238 and the insulating spacer 236 are formed by using the same process operation (refer to FIG. 14), the composition of the dummy structure 238 and the insulating spacer 236 may be the same, and there may be no interface between the dummy structure 238 and the insulating spacer 236.

Referring to FIG. 6, the horizontal extension unit 238b of the dummy structure 238 extending in the direction of the first plug CP1 with respect to the vertical extension unit 238a of the dummy structure 238 may be substantially the same as the horizontal extension unit 236b of the insulating spacer 236 extending in the direction of the dummy structure 238 with respect to the first plug CP1. In other words, an insulating layer arranged between the dummy structure 238 and the first plug CP1 and extending in the horizontal direction may include the horizontal extension unit 238b of the dummy structure 238 and the horizontal extension unit 236b of an insulating spacer 236.

A first length t1 that is a horizontal direction length of the horizontal extension unit 238b of the dummy structure 238 may be substantially the same as a second length t2 that is a horizontal direction length of the horizontal extension unit 236b of the insulating spacer 236. However, the implementation is not limited thereto.

An upper insulating layer 272 may be arranged on the common source layer 210. The upper insulating layer 272 may include a flat upper surface throughout the cell region MCR and the connection region CON. A common source contact 274 penetrating the upper insulating layer 272 and connected to the common source layer 210 may be arranged, and a back surface wiring layer 276 electrically connected to the common source contact 274 may be arranged on the upper insulating layer 272.

A passivation layer 278 covering the back surface wiring layer 276 may be arranged on the upper insulating layer 272. The passivation layer 278 may include an opening unit OP exposing an upper surface of the back surface wiring layer 276.

In general, a plug may land on a step-shaped pad unit connected to a gate electrode in the connection region. However, as the number of layers of the gate electrode increases, there is an issue that the area occupied by the step-shaped pad unit increases. To solve this issue, a step-free contact structure, in which a plug hole penetrating the gate electrode instead of a step-shaped pad unit is formed and an insulating liner is formed on a sidewall of the plug hole, has been proposed.

According to some implementations described above, in the step-free contact structure according to the concepts discussed herein, the manufacturing process of the semiconductor device 100 may be simplified by integrating a process of forming the dummy structure 238 working as a support member at a position adjacent to the plug hole (the first plug hole CP1H) and forming the inside of the support member, and a process of forming the insulating spacer 236 of the plug hole (the first plug hole CP1H).

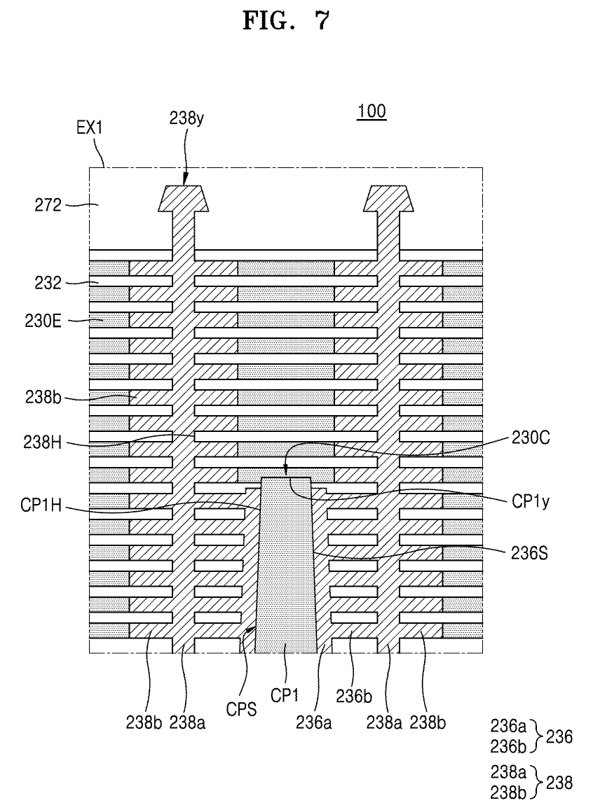

FIG. 7 is an enlarged cross-sectional view of spaces between the first plug CP1 and two of the dummy structures 238 adjacent thereto in a cross-section taken along line B - B' in FIG. 4.

Referring to FIG. 7, because dummy structures 238 are arranged on both sides of one of the first plug CP1, the horizontal extension unit 236b of the insulating spacer 236 surrounding the first plug CP1 may be substantially the same as a horizontal extension unit 238b on the right side of the dummy structure 238 arranged at the left side of the first plug CP1, and the vertical extension unit 236a on the right side of the insulating spacer 236 surrounding the first plug CP1 may be substantially the same as the horizontal extension unit 238b on the left side of the dummy structure 238 arranged on the right side of the first plug CP1. In addition, as described above, because the insulating spacer 236 and the two of the dummy structures 238 are formed simultaneously by using the same process operation, there may be no interface between the insulating spacer 236 and the two dummy structures 238. In some implementations, the two of the dummy structures 238 arranged on both sides of the first plug CP1 may be formed in a mutually mirror symmetrical shape with respect to the first plug CP1.

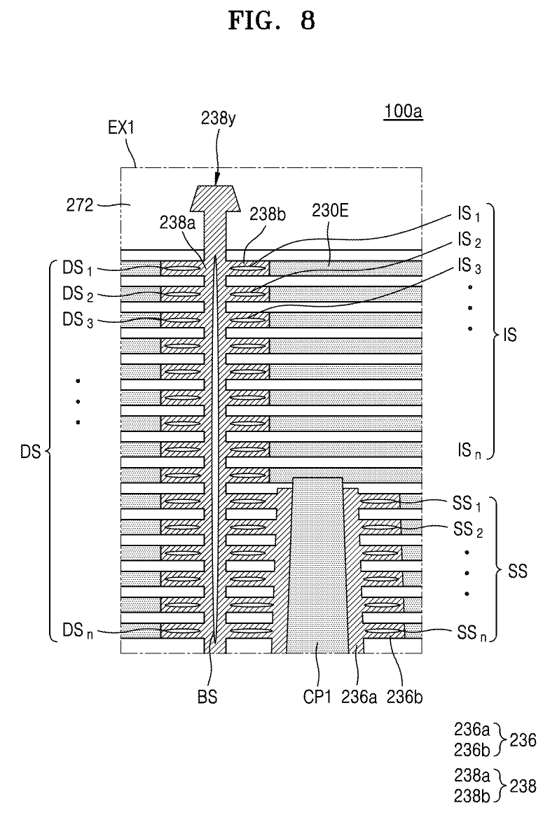

FIG. 8 is another enlarged cross-sectional view of region EX1 in FIG. 5. It will be understood that the semiconductor device 100a of FIG. 8 is not be mutually exclusive to the semiconductor device 100 described with reference to FIGS. 1-7, and components having the same reference numerals are the same components. Hereinafter, duplicate descriptions of the same components are omitted, and differences from the descriptions of the semiconductor device 100 given with reference to FIGS. 1-7 are mainly described.

Referring to FIG. 8, the semiconductor device 100a may include at least one seam inside the insulating spacer 236 and/or the dummy structure 238.

The seam included in the semiconductor device 100a may include a space which remains after an insulating material does not completely fill a gap between the mold insulating layers 232 and the gate extension unit 230E in the process of forming the insulating spacer 236 and the dummy structure 238.

Referring to FIG. 8, the seam may include a dummy unit seam DS arranged on the left side of the horizontal extension unit 238b of the dummy structure 238, a middle unit seam BS arranged on the vertical extension unit 238a of the dummy structure 238, an interconnection unit seam IS arranged on the horizontal extension unit 238b on the right side of the dummy structure 238 (or, the horizontal extension unit 236b on the left side of the insulating spacer 236) arranged between the dummy structure 238 and the first plug CP1, and a spacer unit seam SS of the horizontal extension unit 236b on the right side of the insulating spacer 236. In FIG. 8, it is illustrated that the semiconductor device 100a includes all of the dummy unit seam DS, the middle unit seam BS, the interconnection unit seam IS, and the spacer unit seam SS, but this is only an example, and the semiconductor device 100a may also include only one of these seams. For example, the semiconductor device 100a according to at least one implementation may include only the dummy unit seam DS. Even when the dummy unit seam DS is included, all of dummy unit seams DS₁, DS₂, DS₃, …, DSₙ may be included, or only some of all of the dummy unit seams DS₁, DS₂, DS₃, …, DSₙ may also be included. This kind of configuration may be the same even when the middle unit seam BS and/or the spacer unit seam SS are included.

When the semiconductor device 100a includes the interconnection unit seam IS, the interconnection unit seam IS arranged at a lower end (for example, the interconnection unit seam IS arranged apart from the first plug CP1 in the horizontal direction) may extend to the region of the vertical extension unit 236a of the insulating spacer 236. This configuration may be a structure which is generated as a result of simultaneously forming the dummy structure 238 and the insulating spacer 236 without an interface. When the insulating spacer 236 is formed first and then the dummy structure 238 is formed, the interconnection unit seam IS included in the horizontal extension unit 238b on the right side of the dummy structure 238 may not extend to the region of the insulating spacer 236, and accordingly, an interface may exist between the insulating spacer 236 and the dummy structure 238. However, in the concepts discussed herein, because the process is simplified by simultaneously forming the insulating spacer 236 and the dummy structure 238, the interconnection unit seam IS may extend to a region where the insulating spacer 236 is arranged.

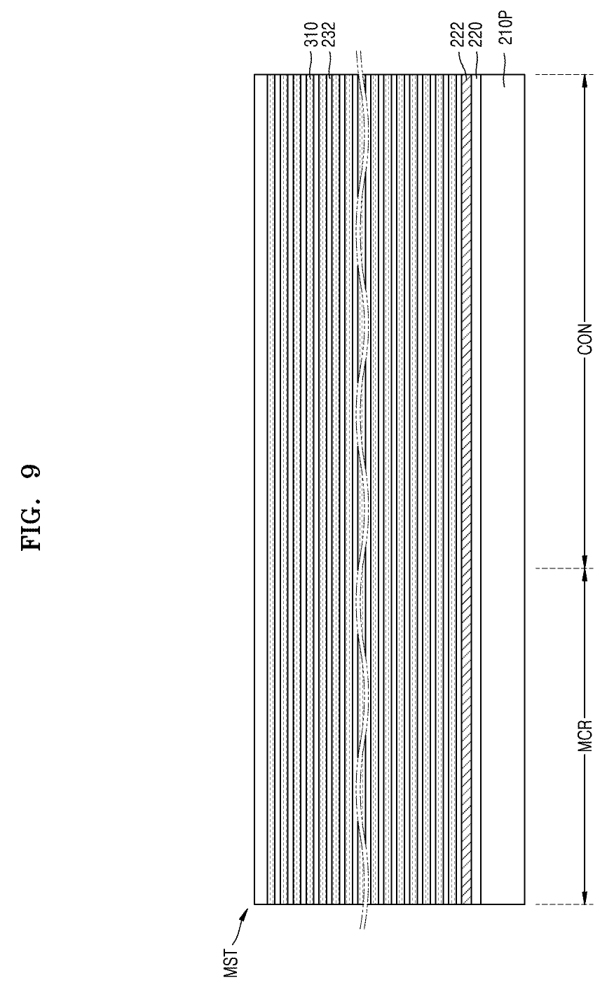

FIGS. 9-21 are cross-sectional views of portions of a method of manufacturing the semiconductor device 100, according to implementations. FIGS. 9-12 and 16-21 are cross-sectional views of the semiconductor device 100 taken along line A - A' in FIGS. 4, and 13-15 are enlarged cross-sectional views of region EX2 in FIG. 12.

Referring to FIG. 9, a buffer insulating layer 220 may be formed on a cell substrate 210P, and the etching stop layer 222 may be formed on the buffer insulating layer 220.

In some implementations, the cell substrate 210P may include at least one of Si, Ge, SiGe, GaAs, InGaAs, AlGaAs, or a combination thereof. The buffer insulating layer 220 may be formed by using silicon oxide. In some implementations, the etching stop layer 222 may be formed by using poly-silicon.

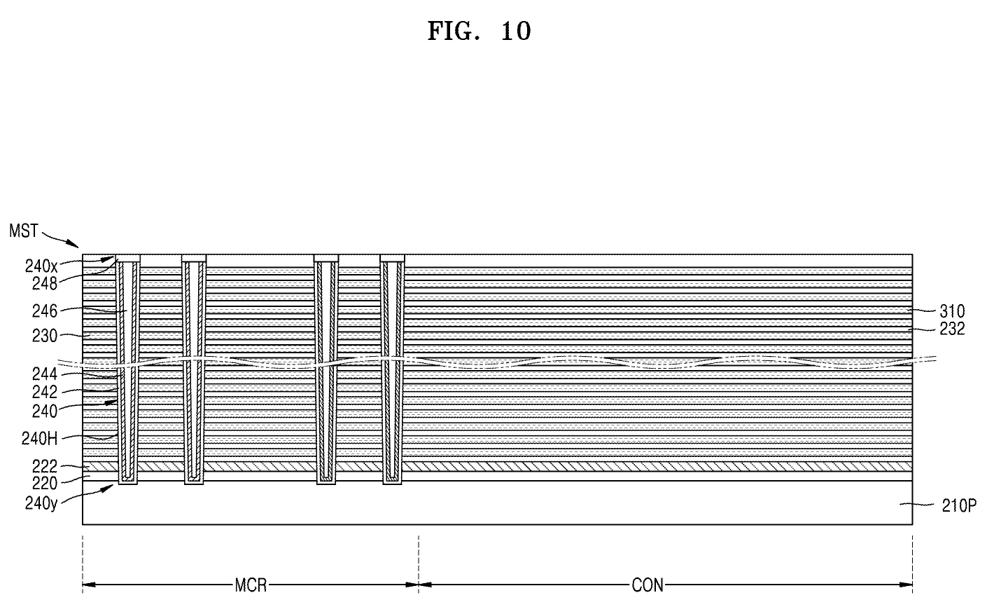

Referring to FIG. 10, a mold stack MST may be formed by alternately forming sacrificial layers 310 and the mold insulating layers 232 on the etching stop layer 222 in the cell region MCR and the connection region CON. In some implementations, the sacrificial layers 310 and the mold insulating layers 232 may be formed by using a material having etch selectivity with respect to each other. For example, the sacrificial layers 310 may include silicon nitride and the mold insulating layers 232 may include silicon oxide.

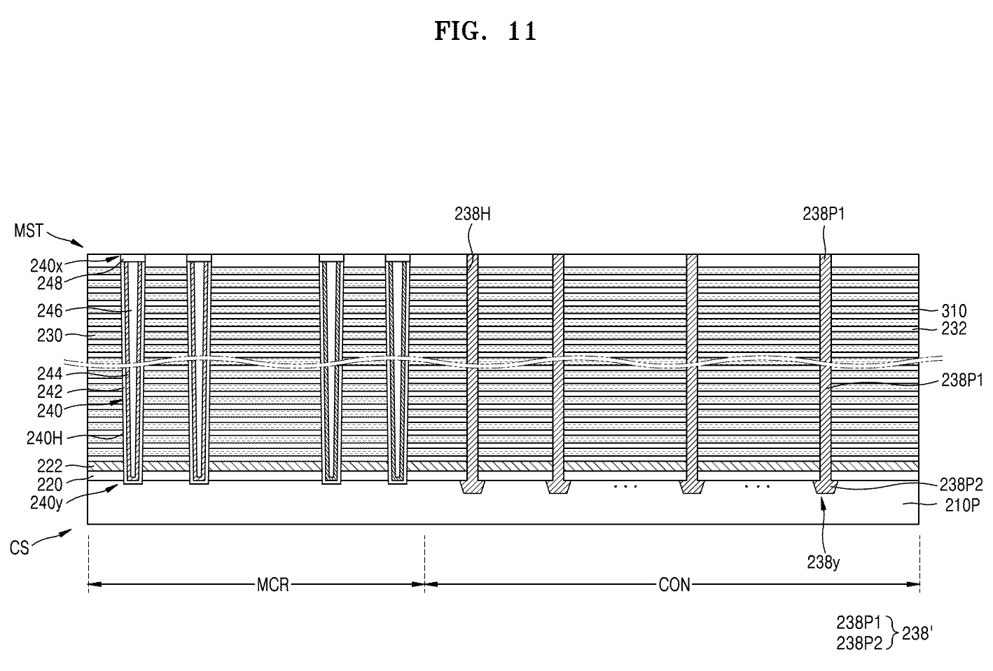

Referring to FIG. 11, in the cell region MCR and the connection region CON, the channel structure 240 and a preliminary dummy structure 238', which penetrate the mold stack MST and extend in the vertical direction (Z direction), respectively, may be formed.

In some implementations, in a process for forming the channel structure 240, the channel hole 240H penetrating the mold stack MST may be formed in the cell region MCR, the gate insulating layer 242, the channel layer 244, and the buried insulating layer 246 may be sequentially formed on the internal wall of the channel hole 240H, and the drain region 248 may be formed at an inlet of the channel hole 240H.

In some implementations, the channel hole 240H may penetrate the mold stack MST, the etching stop layer 222, and the buffer insulating layer 220, extend in the vertical direction (Z direction), and an upper surface of the cell substrate 210P may be exposed at the bottom of the channel hole 240H.

The channel structure 240 may include the first end unit 240x and the second end unit 240y opposite thereto, wherein the first end unit 240x may be arranged adjacent to an upper surface of the mold stack MST or at the same vertical level as the upper surface of the mold stack MST, and the second end unit 240y of the channel structure 240 may be arranged to be in contact with the upper surface of the cell substrate 210P, and at a lower vertical level than the upper surface of the cell substrate 210P. In some implementations, the horizontal direction width of the first end unit 240x of the channel structure 240 may also be greater than the horizontal direction width of the second end unit 240y of the channel structure 240.

In some implementations, in the process of forming the preliminary dummy structure 238', in the connection region CON, a dummy hole 238H penetrating the mold stack MST may be formed, and the preliminary dummy structure 238' filling the internal wall of the dummy hole 238H may be formed.

In some implementations, the dummy hole 238H may penetrate the mold stack MST, the etching stop layer 222, and the buffer insulating layer 220 and extend in the vertical direction (Z direction), and in this process, a portion of the cell substrate 210P may be removed to form a recess in the upper portion of the cell substrate 210P.

The preliminary dummy structure 238' may include a first portion 238P1 and a second portion 238P2, the first portion 238P1 may fill the dummy hole 238H and extend in the vertical direction (Z direction), and the second portion 238P2 may be formed to fill the recess of the cell substrate 210P.

In some implementations, the first portion 238P1 may be filled with an insulating material, and the second portion 238P2 may be filled with a metal material. However, the implementation is not limited thereto. When a gas phase etching (GPE) operation is performed after a first plug hole CP1H is formed in a subsequent process to be described below (refer to FIG. 12), the second portion 238P2 may be filled with a metal material to prevent the possibility of damage to the cell substrate 210P. Accordingly, when the GPE operation is performed, the second portion 238P2 may be filled with a metal material, but when an etching process or a planarization process (for example, a chemical mechanical polishing (CMP) process) other than the GPE process is performed, the second portion 238P2 may also be filled with an insulating material, like the first portion 238P1.

Referring to FIG. 12, the stack cover insulating layer 234 may be formed on the upper surface of the mold stack MST. The stack cover insulating layer 234 may cover the entire upper surface of the mold stack MST in the cell region MCR and the connection region CON. The stack cover insulating layer 234 may have a level of a flat upper surface and bottom surface throughout the cell region MCR and the connection region CON, and may have a certain thickness throughout the cell region MCR and the connection region CON.

Thereafter, in the cell region MCR and the connection region CON, the stack separation opening unit WLH penetrating the mold stack MST and the stack cover insulating layer 234 and extending in the vertical direction (Z direction) may be formed. The stack separation opening unit WLH may extend in the first direction (X direction) (refer to FIG. 4) in the cell region MCR and the connection region CON.

In some implementations, when the process of forming the dummy hole 238H described with reference to FIG. 11 is performed, the stack separation opening unit WLH may also be formed together. A sequence of the process of forming the dummy hole 238H and the process of forming the stack separation opening unit WLH is not limited to the concepts discussed herein.

In the connection region CON, by removing portions of the stack cover insulating layer 234 and the mold stack MST, a plurality of first plug holes CP1H extending in the vertical direction (Z direction) may be formed. The plurality of first plug holes CP1H may be formed in a process of removing a portion of the mold stack MST by using a mask pattern (not illustrated) after the mask pattern is formed on an upper portion of the mold stack MST. The plurality of first plug holes CP1H may have a height varying in the vertical direction (Z direction). The plurality of first plug holes CP1H may have different heights to expose upper surfaces of the sacrificial layers 310 corresponding thereto, among a plurality of sacrificial layers 310.

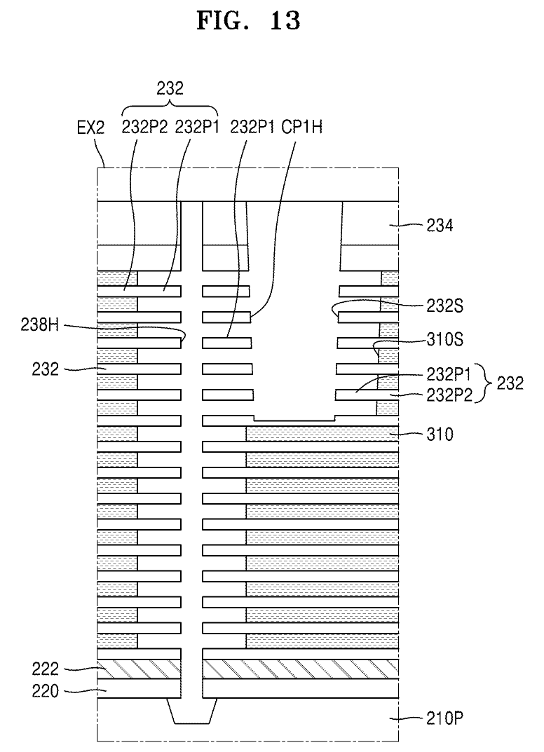

In some implementations, the first portion 238P1 of the preliminary dummy structure 238' may be removed when the plurality of first plug holes CP1H are formed. As illustrated in FIG. 12, the second portion 238P2 filling the recess formed in the upper portion of the cell substrate 210P may remain. After the mask pattern is removed, the GPE process may be performed, and when the GPE process is completed, the second portion 238P2 may also be subsequently removed (refer to FIG. 13).

As described above, when an etching process or a planarization process other than the GPE process is used, the second portion 238P2 may be filled with an insulating material rather than a metal material, and thus may be removed together with the first portion 238P1 in a process of removing the first portion 238P1.

In some implementations, the first plug hole CP1H may include a first hole H1 exposing the upper surface of the sacrificial layer 310 at the uppermost portion, a second hole H2 exposing the upper surface of the sacrificial layer 310 directly under the sacrificial layer 310 at the uppermost portion (for example, the second hole H2 exposing the upper surface of the sacrificial layer 310 at the second uppermost portion), a third hole H3 exposing the upper surface of the sacrificial layer 310 at the third uppermost portion from the upper surface of the mold stack MST, and an mth hole Hm exposing the upper surface of the mth sacrificial layer 310 from the upper surface of the mold stack MST.

Referring to FIG. 13, a recess process may be performed to remove a portion of the sacrificial layer 310 exposed on the internal walls of the plurality of first plug holes CP1H and the dummy holes 238H.

In some implementations, the recess process may include a process for removing a sidewall portion of the sacrificial layer 310 exposed on the sidewalls of the plurality of first plug holes CP1H and the dummy hole 238H by a certain thickness, and in the recess process, portions of the sacrificial layers 310 exposed on the sidewalls of the plurality of first plug holes CP1H and portions of the sacrificial layers 310 exposed on the sidewalls of the dummy holes 238H may be removed at similar or equal thicknesses. In some implementations, the recess process may include a wet etching process or a dry etching process using an etchant containing phosphoric acid.

As the sidewall portions of the sacrificial layers 310 exposed on the sidewalls of the plurality of first plug holes CP1H and the dummy hole 238H are removed by using the recess process, a sidewall 310S of the sacrificial layer 310 may be sunk or recessed inwardly with respect to covers a sidewall 232S of the mold insulating layer 232. Accordingly, the mold insulating layer 232 may include a second portion 232P2 arranged between two of the mold insulating layers 232 adjacent to each other in the vertical direction (Z direction), and a first portion 232P1 which is integrally formed with the second portion 232P2, extends in the horizontal direction, but is not in contact with the sacrificial layer 310 in a region protruding from the sidewall 310S of the sacrificial layer 310. In some implementations, as illustrated in FIG. 13, only the first portion 232P1 of the mold insulating layer 232 may be arranged in a region between the dummy hole 238H and the first plug hole CP1H.

Referring to FIG. 14, an insulating spacer 236 covering the sidewalls and bottom portions of the first plug hole CP1H and a dummy structure 238 filling the dummy hole 238H may be formed, and the remaining spaces of the first plug hole CP1H may be filled with preliminary first plugs CP1'.

In some implementations, the insulating spacer 236 may include the vertical extension unit 236a and the horizontal extension unit 236b. As described above, the vertical extension unit 236a of the insulating spacer 236 may be formed to have a constant thickness along the insulating walls of the plurality of first plug holes CP1H, and the horizontal extension unit 236b of the insulating spacer 236 may be formed in one body with the vertical extension unit 236a, and extend from the vertical extension unit 236a in a horizontal direction. In this case, the horizontal extension unit 236b of the insulating spacer 236 may extend to the sidewall of the sacrificial layer 310 (refer to 310S in FIG. 13). In other words, the horizontal extension unit 236b of the insulating spacer 236 may be in contact with the sacrificial layer 310.

In some implementations, the dummy structure 238 may include the vertical extension unit 238a and the horizontal extension unit 238b. As described above, the vertical extension unit 238b of the dummy structure 238 may be formed along the internal wall of the dummy hole 238H to fill the inner space of the dummy hole 238H, and the horizontal extension unit 238b of the dummy structure 238 may be formed in one body with the vertical extension unit 238a and may extend from the vertical extension unit 238a in the horizontal direction. In this case, the horizontal extension unit 238b of the dummy structure 238 may extend to the sidewall of the sacrificial layer 310 (refer to 310S in FIG. 13). In other words, the horizontal extension unit 238b of the dummy structure 238 may be in contact with the sacrificial layer 310.

Because the first portion 232P1 of the mold insulating layer 232 is surrounded by the insulating spacer 236 and/or the dummy structure 238 as the insulating spacer 236 and the dummy structure 238 are formed, all empty spaces between neighboring mold insulating layers 232 may be filled in this forming process.

In some implementations, the vertical extension unit 236a of the insulating spacer 236, the horizontal extension unit 236b of the insulating spacer 236, the vertical extension unit 238a of the dummy structure 238, and the horizontal extension unit 238b of the dummy structure 238 may be simultaneously formed. Accordingly, because the insulating spacer 236 and the dummy structure 238 are substantially formed in one body (also referred to as integrally formed or integrally connected), there may be no interface between the insulating spacer 236 and the dummy structure 238. In addition, because the insulating spacer 236 and the dummy structure 238 are simultaneously formed, the seam formed between the horizontal extension units 236b (or, the horizontal extension unit 238b) arranged between the insulating spacer 236 and the dummy structure 238 may also extend to a region of the vertical extension unit 236a of the insulating spacer 236 (refer to FIG. 8).

According to the concepts discussed herein, the insulating spacer 236 and the dummy structure 238 may be simultaneously formed, and thus the manufacturing process of the semiconductor device 100 may be simplified.

As illustrated in FIG. 14, the remaining spaces of the first plug hole CP1H may be filled with the preliminary first plug CP1' after the insulating spacer 236 is formed. In some implementations, the preliminary first plug CP1' may include an insulating material.

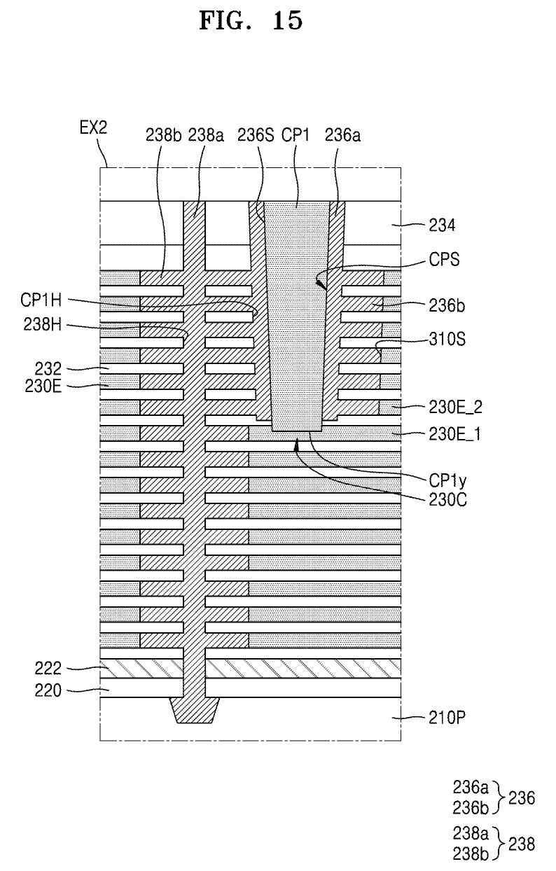

Referring to FIG. 15, the sacrificial layer 310 may be removed, and the gate electrode 230 may be formed by using a metal material in the space from which the sacrificial layer 310 has been removed. Next, the preliminary first plug CP1' may be removed, and the first plug CP1 may be formed inside the first plug hole CP1H.

As the plurality of sacrificial layers 310 are respectively replaced with the plurality of gate electrodes 230, the plurality of gate electrodes 230 may extend in the cell region MCR and the connection region CON in the horizontal direction. The gate electrodes 230 arranged in the connection region CON may be referred to as the gate extension unit 230E. The plurality of gate extension units 230E may overlap each other in the connection region CON in the vertical direction (Z direction). For example, the plurality of gate extension units 230E arranged at different vertical levels in the connection region CON may have the same width in the horizontal direction.

In some implementations, the plurality of gate extension units 230E arranged in the connection region CON may be arranged to surround the insulating spacer 236 and the dummy structure 238, and the corresponding insulating spacer 236 may be arranged between one of the first plug hole CP1H and each of a plurality of gate extension units 230E.

In some implementations, in a process of removing the preliminary first plug CP1', a portion of the insulating spacer 236 formed at the bottom portion of the first plug hole CP1H may be removed together. In other words, the first plug CP1 may be filled up to the second end unit CP1y of the first plug hole CP1H.

In some implementations, the bottom surface of the first plug CP1 may be in contact with the gate contact surface 230C, and accordingly, one of the first plug CP1 may be electrically connected to the gate extension unit 230E corresponding to the one of the first plug CP1 via the gate contact surface 230C. In some implementations, a side surface CPS of the first plug CP1 may be in contact with a sidewall 236S of the insulating spacer 236.

For example, the bottom surface of one of the first plug CP1 may be electrically connected to the gate extension unit 230E corresponding thereto (for example, the first gate electrode extension unit 230E_1), while the sidewall of one of the first plug CP1 may not be electrically connected to the gate extension unit 230E (for example, the second gate electrode extension unit 230E_2) arranged at a higher vertical level than the gate extension unit 230E corresponding to the sidewall (for example, the first gate electrode extension unit 230E_1). The insulating spacer 236 may be arranged between the gate extension unit 230E corresponding thereto (for example, the second gate electrode extension unit 230E_2 arranged at a higher vertical level than the first gate electrode extension unit 230E_1) (for example, the second gate electrode extension unit 230E_2) and the sidewall of one of the first plug CP1, and accordingly, the gate extension unit 230E (for example, the second gate electrode extension unit 230E_2) arranged at a higher vertical level than the gate extension unit 230E corresponding to the insulating spacer 236 (for example, the first gate electrode extension unit 230E_1) may be insulated from the sidewall of the one of the first plug CP1.

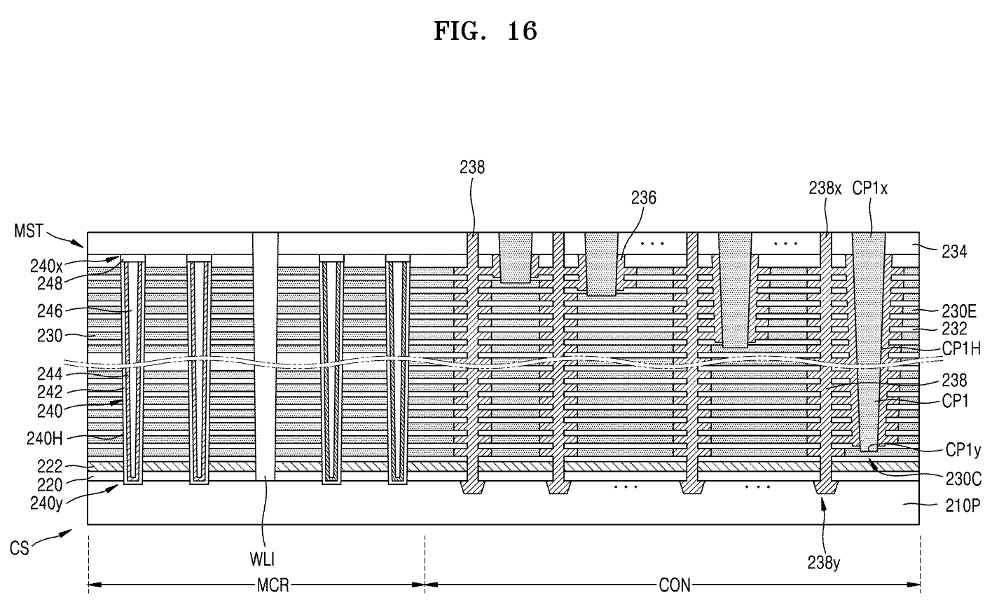

Referring to FIG. 16, the stack separation insulating layer WLI may be formed inside the stack separation opening unit (refer to WLH in FIG. 12).

As illustrated in FIG. 16, the first end unit CP1x of the plurality of first plugs CP1 may all be arranged at the same vertical level, and in addition, may be arranged at the same vertical level as the upper surface of the stack cover insulating layer 234. The second end units CP1y of the plurality of first plugs CP1 may be arranged at different vertical levels, and for example, each of the second end units CP1y of the plurality of first plugs CP1 may be arranged on the gate contact surface 230C corresponding to each of the second end unit CP1y.

All of the first end units 238x of the plurality of dummy structures 238 may be arranged at the same vertical level, and in addition, may be arranged at the same vertical level as the upper surface of the stack cover insulating layer 234. All of the second end units 238y of the plurality of dummy structures 238 may be arranged at the same vertical level, and for example, bottom surfaces of the second end units 238y of the plurality of dummy structures 238 may be arranged at a vertical level lower than the upper surface of the cell substrate 210P.

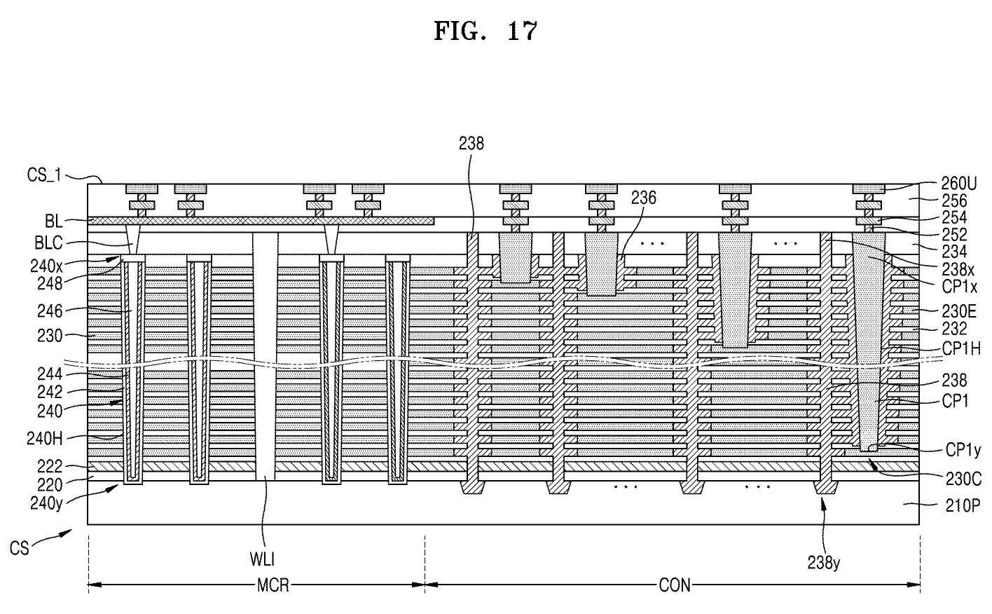

Referring to FIG. 17, the bit line contact BLC and the bit line BL, which are electrically connected to the channel structure 240, may be formed.

Thereafter, the connection via 252 electrically connected to the bit line BL and the first plug CP1, the connection wiring layer 254, and the interlayer insulating layer 256 may be formed. A connection pad 260_U may be formed on an upper surface of the interlayer insulating layer 256.

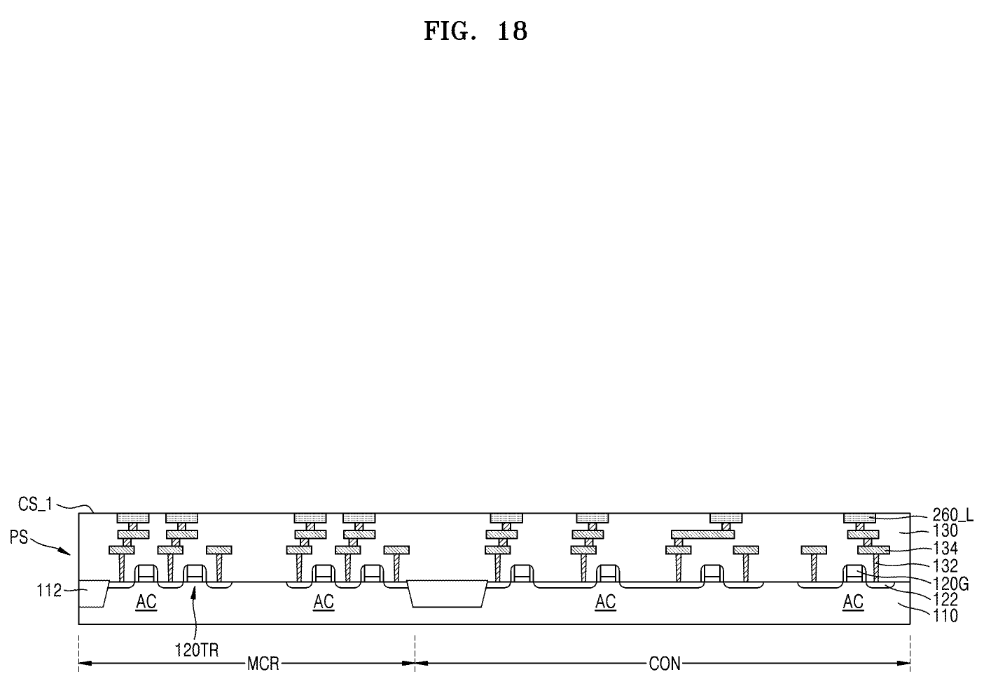

Referring to FIG. 18, the periphery circuit structure PS may be prepared.

The periphery circuit transistor 120TR may be formed on the substrate 110 in which the active region AC is defined by the device separation layer 112; the plurality of peripheral circuit transistors 120TR, and the plurality of periphery circuit contacts 132 and the plurality of periphery circuit wiring layers 134, which are electrically connected to the substrate 110, may be formed on the substrate 110; and the periphery circuit transistor 120TR, and the interlayer insulating layer 130 covering the plurality of periphery circuit contacts 132 and the plurality of periphery circuit wiring layers 134 may be formed. A connection pad 260_L may be formed on the upper surface of the interlayer insulating layer 130.

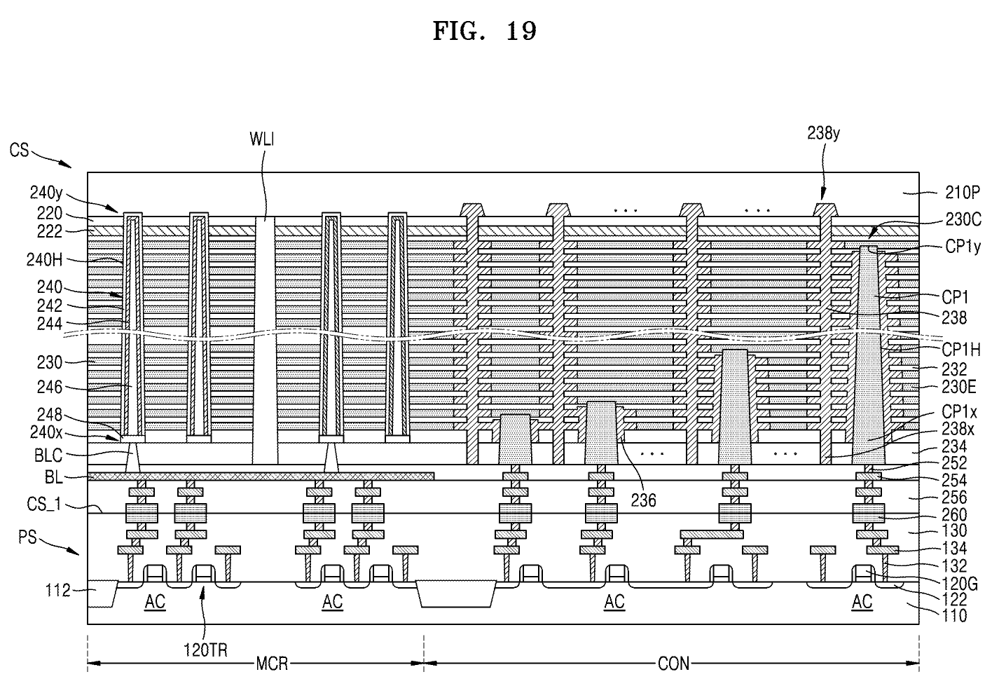

Referring to FIG. 19, the periphery circuit structure PS may be attached to the cell structure CS. The periphery circuit structure PS and the cell structure CS may be attached to each other by using a metal-oxide hybrid bonding method via the connection pad 260 and the interlayer insulating layers 130 and 256, but the implementation is not limited thereto.

Thereafter, a structure, to which the periphery circuit structure PS and the cell structure CS are attached, may be inverted so that the substrate 110 faces upward.

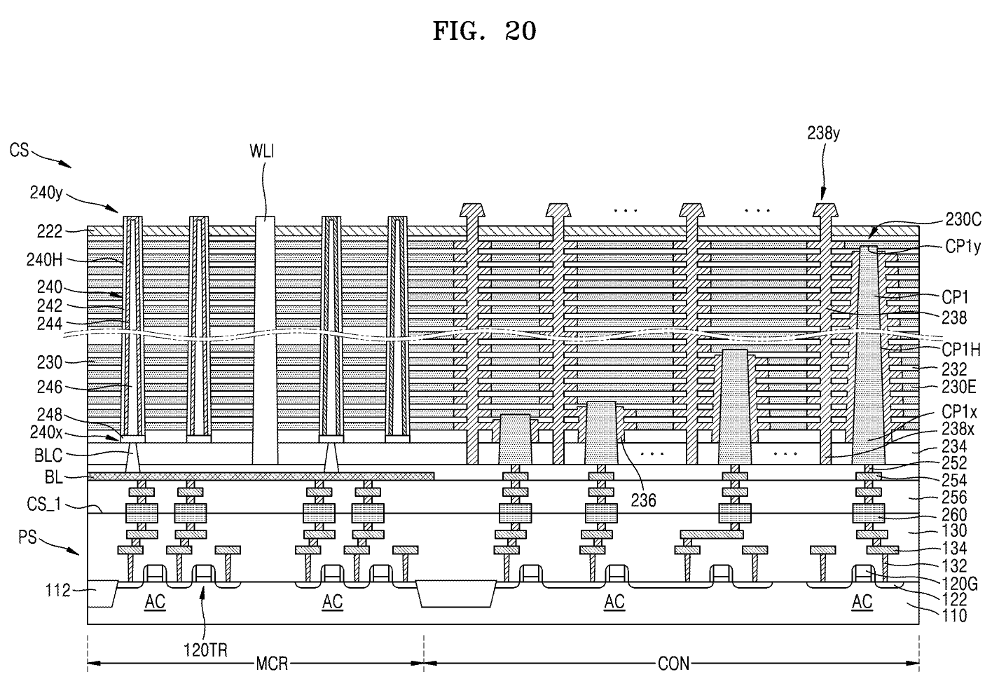

Referring to FIG. 20, the cell substrate 210P (refer to FIG. 19) may be removed. The cell substrate 210P may be removed by using a grinding process and a subsequent etching process, and the buffer insulating layer 220 (refer to FIG. 19) may be exposed.

Thereafter, the buffer insulating layer 220 may also be removed, and the upper surface of the etching stop layer 222 may be exposed. As the buffer insulating layer 220 is removed, the second end unit 240y of the channel structure 240 may protrude from the upper surface of the etching stop layer 222.

As the cell substrate 210P and the buffer insulating layer 220 are removed, an upper side of the stack separation insulating layer WLI and an upper side of the dummy structure 238 may also be exposed, and may protrude above the etching stop layer 222.

Thereafter, the upper surface of the channel layer 244 may be exposed by removing the portion of the gate insulating layer 242 exposed to the second end unit 240y of the channel structure 240. In some implementations, the upper surface of the gate insulating layer 242 may be arranged on the same plane as the upper surface of the channel layer 244.

In other implementations, in a process of removing the gate insulating layer 242, the process of removing the gate insulating layer 242 may be performed so that the upper surface of the etching stop layer 222 is exposed. In some implementations, the upper side of the gate insulating layer 242 may be removed so that the gate insulating layer 242 is arranged at a lower level than the upper surface of the channel layer 244 and portions of the upper surface and the sidewall of the channel layer 244 are exposed.

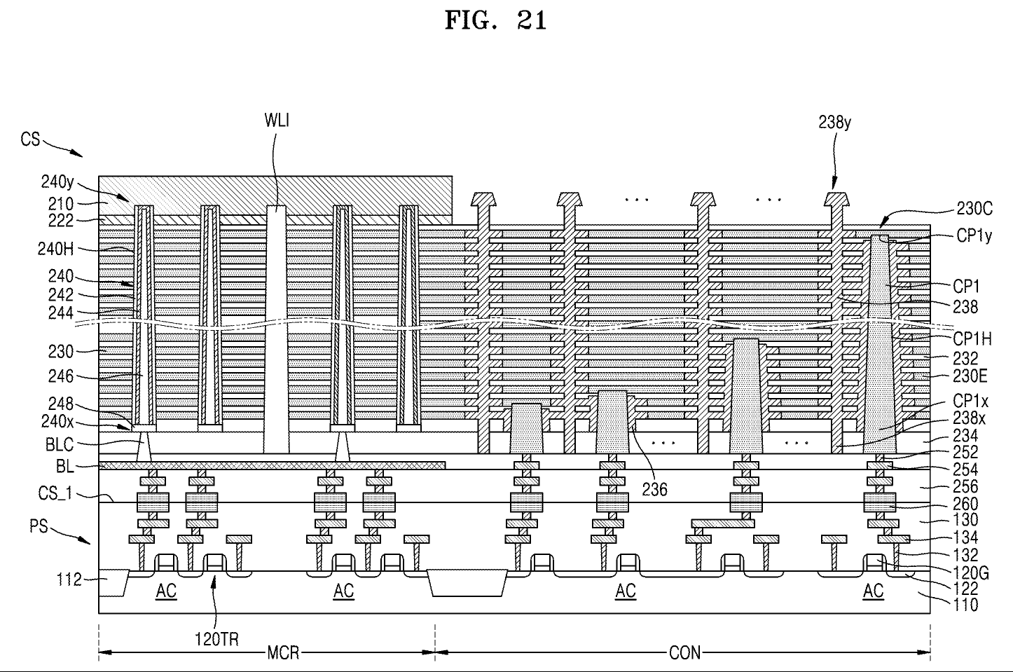

Referring to FIG. 21, the common source layer 210 may be formed in the cell region MCR, the connection region CON, and the periphery circuit connection region PRC. The common source layer 210 may include polysilicon. For example, the common source layer 210 may include polysilicon doped with n-type impurities. In the cell region MCR, the common source layer 210 may be conformally formed on the exposed upper surfaces of the etching stop layer 222 and the channel layer 244.

Portions of the common source layer 210 and the etching stop layer 222 arranged in the connection region CON and the periphery circuit connection region PRC may be removed.

Referring to FIG. 5 again, an upper insulating layer 272 may be formed on the common source layer 210 and the mold insulating layer 232 that is uppermost in the cell region MCR, the connection region CON, and the periphery circuit connection region PRC.

Thereafter, a mask pattern may be formed on the upper insulating layer 272, and a portion of the upper insulating layer 272 may be removed by using the mask pattern as an etching mask to form a back surface contact hole. A common source contact 274 may be formed inside the back surface contact hole, and a back surface wiring layer 276 electrically connected to the common source contact 274 may be formed on the upper insulating layer 272.

Thereafter, a passivation layer 278 covering the back surface wiring layer 276 may be formed on the upper insulating layer 272, and the opening unit OP may be formed in the passivation layer 278 to expose an upper surface of the back surface wiring layer 276.

By performing the processes described above, the semiconductor device 100 of FIG. 5 may be completely manufactured.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As described above, implementations have been disclosed in the drawings and the concepts discussed herein. While the implementations have been described herein with reference to specific terms, it should be understood that they have been used only for the purpose of describing the technical idea of the concepts discussed herein and not for limiting the scope of the concepts discussed herein as defined in the claims. Thus, those with ordinary skill in the art will appreciate that various modifications and equivalent implementations are possible without departing from the scope of the concepts discussed herein. Accordingly, the true scope of protection of the concepts discussed herein should be determined by the technical idea of the following claims.

What is claimed is:

1. A semiconductor device comprising:
a periphery circuit structure; and
a cell structure on the periphery circuit structure, comprising:
a cell region,
a connection region,
a plurality of gate electrodes,
a plurality of mold insulating layers alternately arranged with the plurality of gate electrodes on the cell region and the connection region in a first direction that is perpendicular to an upper surface of the periphery circuit structure,
a channel structure configured to extend into the plurality of gate electrodes in the first direction,
a contact plug in contact with a first gate electrode of the plurality of gate electrodes in the connection region, wherein the contact plug extends into at least one second gate electrode of the plurality of gate electrodes that is under the first gate electrode,
a dummy structure comprising a body that extends in the first direction and a plurality of protrusion units that extend from the body in a second direction that crosses the first direction, and
a plurality of insulating spacers surrounding the contact plug and connected to at least one protrusion unit of the plurality of protrusion units, each insulating spacer of the plurality of insulating spacers comprising vertical extension units in contact with at least one sidewall of the contact plug, and horizontal extension units that extend from the vertical extension unit in the second direction.

2. The semiconductor device of claim 1, wherein
the at least one protrusion unit of the plurality of protrusion units is substantially identical to a first horizontal extension unit, of the horizontal extension units, that extends in a third direction towards the dummy structure .

3. The semiconductor device of claim 2, wherein the at least one protrusion unit is spaced apart from the first horizontal extension unit.

4. The semiconductor device of claim 1, wherein the dummy structure and the plurality of insulating spacers comprise an identical material.

5. The semiconductor device of claim 1, the cell structure comprising a plurality of contact plugs including the contact plug, wherein
the plurality of contact plugs have different heights.

6. The semiconductor device of claim 5, wherein each contact plug of the plurality of contact plugs is in contact with at least two or more dummy structures.

7. The semiconductor device of claim 1, comprising
a stack cover insulating layer under a gate electrode of the plurality of gate electrodes that is lowermost among the plurality of gate electrodes;
a bit line arranged under the channel structure and electrically connected to the channel structure; and
a connection pad electrically connected to the bit line and positioned between the periphery circuit structure and the cell structure, wherein
a contact plug first end unit of the contact plug extends into the stack cover insulating layer.

8. The semiconductor device of claim 7,
wherein the contact plug comprises a contact plug second end unit opposite to the contact plug first end unit, and
wherein the contact plug second end unit is in contact with the first gate electrode.

9. The semiconductor device of claim 8,
wherein the dummy structure comprises a dummy structure first end unit and a dummy structure second end unit opposite to the dummy structure first end unit,
wherein the dummy structure first end unit is on an identical vertical level with the contact plug first end unit, and
wherein the dummy structure second end unit is at a higher vertical level than the contact plug second end unit.

10. The semiconductor device of claim 1, wherein
a length in the second direction of the plurality of protrusion units of the dummy structure is identical to a length in the second direction of the horizontal extension units of an insulating spacer of the plurality of insulating spacers.

11. A semiconductor device comprising:
a periphery circuit structure; and
a cell structure on the periphery circuit structure, comprising:
a cell region,
a connection region,
a plurality of gate electrodes,
a plurality of mold insulating layers alternately arranged with the plurality of gate electrodes on the cell region and the connection region in a first direction that is perpendicular to an upper surface of the periphery circuit structure,
a channel structure that extends into the plurality of gate electrodes in the first direction,
a contact plug in contact with a first gate electrode of the plurality of gate electrodes in the connection region, and extend into at least one second gate electrode of the plurality of gate electrodes that is under the first gate electrode,
a first dummy structure comprising a body adjacent to the contact plug, the body comprising:
a first side surface that extends in the first direction and faces the contact plug; and
a second side surface opposite to the first side surface,
a plurality of first protrusion units that extend from the first side surface in a second direction that crosses the first direction, and a plurality of second protrusion units that extend from the second side surface in the second direction, and
an insulating spacer comprising
vertical extension units surrounding the contact plug and spaced apart from each other in the first direction, the vertical extension units in contact with sidewalls of the contact plug;
a plurality of first horizontal extension units that extend from respective vertical extension units in a direction toward the first dummy structure; and
a plurality of second horizontal extension units that extend in a direction opposite to the first dummy structure,
wherein the plurality of first horizontal extension units of the insulating spacer interface with the plurality of first protrusion units of the first dummy structure, and
wherein the first dummy structure and the insulating spacer are spaced apart.

12. The semiconductor device of claim 11, wherein the first dummy structure comprises at least one seam.

13. The semiconductor device of claim 11, wherein each of the plurality of first and second protrusion units of the first dummy structure comprises at least one seam.

14. The semiconductor device of claim 11, wherein each of the plurality of first and second horizontal extension units of the insulating spacer comprises at least one seam.

15. The semiconductor device of claim 14, wherein the at least one seam extends to at least a partial region of the vertical extension units of the insulating spacer.

16. The semiconductor device of claim 11,
comprising a second dummy structure adjacent to the contact plug and arranged in a direction opposite to the first dummy structure,
wherein the plurality of second horizontal extension units of the insulating spacer are integrally connected to the second dummy structure.

17. The semiconductor device of claim 16, wherein the second dummy structure comprises a substantially identical material to the first dummy structure.

18. The semiconductor device of claim 11, wherein a length in the first direction of the first dummy structure is greater than a length in the first direction of the contact plug.

19. A semiconductor device comprising:
a periphery circuit structure; and
a cell structure on the periphery circuit structure, comprising:
a cell region,
a connection region,
a plurality of gate electrodes,
a plurality of mold insulating layers alternately arranged with the plurality of gate electrodes in the cell region and the connection region in a first direction that is perpendicular to an upper surface of the periphery circuit structure,
a channel structure on the cell region that extends into the plurality of gate electrodes in the first direction,
a bit line arranged under the channel structure and electrically connected to the channel structure,
in the cell region and the connection region, a stack cover insulating layer under a gate electrode of the plurality of gate electrodes that is lowermost among the plurality of gate electrodes,
a contact plug in contact with a first gate electrode of the plurality of gate electrodes in the connection region, wherein the contact plug extends into at least one second gate electrode of the plurality of gate electrodes that is under the first gate electrode, the contact plug comprising a first end unit and a second end unit opposite to the first end unit, wherein the first end unit is closer to the peripheral circuit structure than the second end unit,
a plurality of insulating spacers on at least one sidewall of the contact plug, each insulating spacer of the plurality of insulating spacers comprises a horizontal extension unit that extends in a second direction that crosses the first direction, and
a dummy structure comprising a body that extends in the first direction and a plurality of protrusion units that extend from the body in the second direction,
wherein at least one protrusion unit of the plurality of protrusion units is identical to the horizontal extension unit.

20. The semiconductor device of claim 19, wherein the dummy structure and the plurality of insulating spacers comprise an identical material.
